(19) United States
(12) Patent Application Publication
(10) Pub. No.: US 2004/0166687 A1
(43) Pub. Date: Aug. 26, 2004

(54) Method for forming a polycide gate and structure of the same

(76) Inventors: Yung-Chang Lin, Feng-Yuan City (TW); Le-Tien Jung, Hsin-Chu City (TW); Wen-Jeng Lin, Pan-Chiao City (TW)

Correspondence Address: Nath & Associates, PLLC, Sixth Floor, 1030 15th Street, N.W., Washington, DC, 20005, US

(21) Appl. No.: 10/373,098

(22) Filed: Feb. 26, 2003

(51) Int. Cl. H01L 21/311

(52) U.S. Cl. 438/694

(57) ABSTRACT

The method of forming a polycide gate includes forming a pad oxide layer on a substrate. A first conductive layer is formed on the pad oxide layer. Subsequently, a first ion implantation into the first conductive layer is next performed to form deep implantation region of polysilicon. Successively, a second ion implantation into the first conductive layer is performed to form shallow implantation region of polysilicon, wherein the second ion type is the same as the first ion type. A second conductive layer formed on the first conductive layer. A further patterned photoresist layer is formed on the second conductive layer. Next, a dry etching process one time by way of using the patterned photoresist layer as an etching mask is performed to etch through in turn the second conductive layer, the first conductive layer and the pad oxide layer until forming a gate with double polysilicon implantation, thereby forming a polycide gate. Finally, the photoresist layer is then removed.

### BACKGROUND OF THE INVENTION

1. Field of the Invention

The present invention relates to a gate of semiconductor device, and more specifically, to a method for forming a polycide gate with double polysilicon implantation and the structure of the same.

2. Description of the Prior Art

The semiconductor industry has been advanced to the field of Ultra Large Scale Integrated (ULSI) technologies. The fabrication of the nonvolatile memories also follows the trend of the size reduction of a device. Thanks to their advantages, such as non-volatility, fast access time and low power dissipation, non-volatile memory can be applied as portable handy equipments, solid-state camera and PC cards. As known in the art, the nonvolatile memories are currently used in electronic devices to store structure data, program data and other data during repeated reading and writing operations. Different types of devices have been developed for specific applications. These parts have been developed with a focus on the high endurance and high-speed requirements. EEPROM needs multi-layer of polysilicon and silicon dioxide, therefore, multi-masking are used during the fabrication, thereby increasing the time for manufacturing the devices. One of the present researches is focus on how to integrate the manufacture process to reduce the cost. One of the approaches is to integrate the memory process with the CMOS fabrication.

As devices are made smaller, a major problem with semiconductor manufacturing is the forming of smaller gate length or widths while maintaining gate performance and forming proper low resistance silicide contacts. The gate must be narrow at the substrate to reduce the channel length but must be wide enough so that proper salicide contacts can be formed to the top of the gate. This is particularly important as gate width (or lengths decrease below 0.25 mu.m). In order to increase the operation frequency of a device, it is in general required to shorten a length of a gate. However, further shortening of the gate length, which is about 1 mu.m causes gate resistance to increase due to a smaller aspect ratio.

In a semiconductor device, a metal-oxide-semiconductor field-effect transistor (MOSFET) is one of the most important elements for the VLSI integrated circuits. A MOSFET includes a gate structure, a source and a drain, wherein the source and drain are located at the sides of the gate structure. The gate structure includes a metal layer at the top referred to as gate electrode, an oxide layer under the metal layer referred to as gate oxide, and a semiconductor layer at the bottom.

The category of semiconductor devices that is commonly referred to as Field Effect Devices (FET's) forms an important class of devices that has, as a consequence, received a considerable amount of attention in its construction and the many refinements that have been applied to this to construction. The main thrust of the refinements that have been applied to these devices has been provided by the continued decrease in device size that has led to continued device improvements. In its simplest form, the FET consists of a gate electrode structure, typically formed of polysilicon that is formed on the surface of a layer of gate oxide that has been deposited on the surface of a semiconductor substrate. Self-aligned with and adjacent to the gate electrode are two regions in the surface of the substrate of opposite conductivity type that are referred to as the source and the drain regions. Points of electrical contact are established to the source and drain regions in addition to the surface region of the gate electrode.

Typically, the metal layer at the top of the gate structure is formed of polysilicon; thereby the gate structure is referred to as poly gate. Because poly-silicon does not have a lowest resistance, sometimes a layer of suicide is deposited overlying the poly-silicon layer to form a polycide gate for lowering the resistance.

Therefore, this invention provides a method that can reduce polycide gate vertical contact resistance by means of more ion implantation concentration of surface of polysilicon layer.

### SUMMARY OF THE INVENTION

The object of the present invention is to disclose a method for forming a polycide gate and structure of the same.

The further object of the present invention is to disclose a polycide gate with double polysilicon implantation region.

The steps of the present invention include forming a pad oxide layer on a substrate. A first conductive layer is formed on the pad oxide layer. Subsequently, a first ion implantation into the first conductive layer is next performed to form deep implantation region of polysilicon. Successively, a second ion implantation into the first conductive layer is performed to form shallow implantation region of polysilicon, wherein the second ion type is the same as the first ion type.

Then, a second conductive layer is formed on the first conductive layer. A silicon nitride layer is formed on the silicide layer. A further patterned photoresist layer is formed on the second conductive layer.

Next, a dry etching process one time by way of using the patterned photoresist layer as an etching mask is performed to etch through in turn the silicon nitride layer, the second conductive layer, the first conductive layer, and the pad oxide layer until forming a gate with double implantation region of the polysilicon, thereby forming a polycide gate. Finally, the patterned photoresist layer is then removed.

The structure of the polycide gate includes a gate oxide layer formed on a substrate. A first conductive layer as the same gate length with the gate oxide layer is formed on the gate oxide layer. A second conductive layer as the same gate length with the conductive layer is formed on the polysilicon layer. A second conductive layer as the same gate length with the first conductive layer is formed on the titanium nitride layer. A silicon nitride layer has the same gate length with the second conductive layer.

### BRIEF DESCRIPTION OF THE DRAWINGS

The foregoing aspects and many of the attendant advantages of this invention will become more readily appreciated as the same becomes better understood by reference to the following detailed descriptions, when taken in conjunction with the accompanying drawings, wherein:

FIG. 1 is the cross sectional view of a substrate illustrating the step of forming a deep implantation region of polysilicon according to the present invention;

FIG. 2 is the cross sectional view of a substrate illustrating the step of forming a shallow implantation region of polysilicon according to the present invention;

FIG. 3 is the cross sectional view of a substrate illustrating the step of forming a titanium nitride layer according to the present invention;

FIG. 4 is the cross sectional view of a substrate illustrating the step of forming a silicide layer according to the present invention;

FIG. 5 is the cross sectional view of a substrate illustrating the step of forming a silicon nitride layer according to the present invention;

FIG. 6 is the cross sectional view of a substrate illustrating the step of forming a patterned photoresist layer according to the present invention; and

FIG. 7 is the cross sectional view of a substrate illustrating the step of forming a polycide gate according to the present invention.

### DESCRIPTION OF THE PREFERRED EMBODIMENT

The present invention proposes a novel method to fabricate the polycide gate and the structure of the same. The aspect of the present invention includes that the polycide gate has a double implantation region of polysilicon. The detail description of the method will be seen as follows.

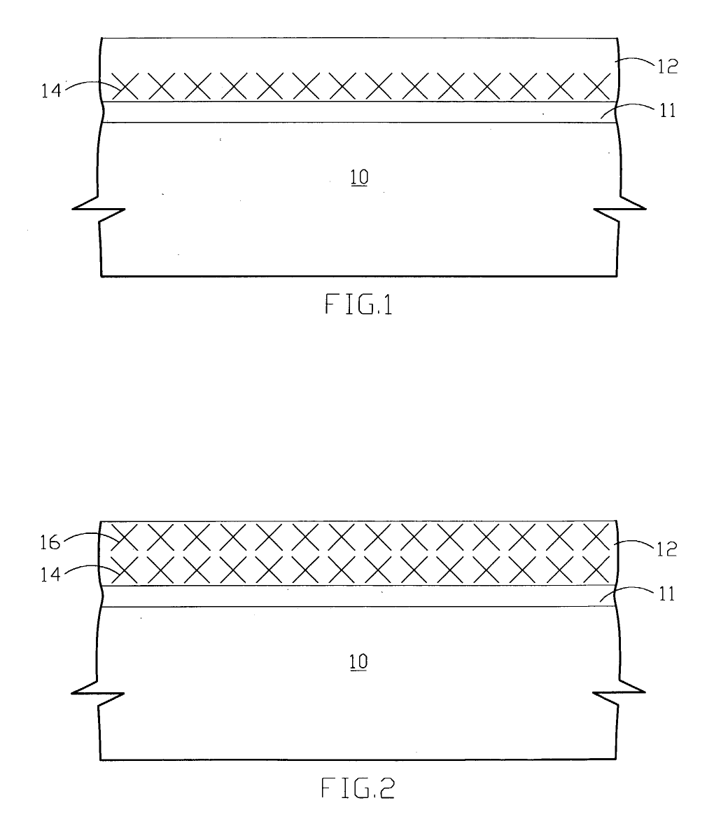

Turning to FIG. 1, it shows the cross sectional view of forming a deep implantation region of polysilicon according to the present invention. The first procedure of the present invention is to form the silicon dioxide layer 11 on a substrate 10.

The substrate 10 for forming a gate of semiconductor device according to the present invention suitably includes a single crystal wafer 10 with a <100> or <111> crystallographic orientation. Other substrate material may be used. In a preferred embodiment, a silicon dioxide layer 11 is formed to a thickness of about 10 to 100 angstroms. However, the silicon dioxide layer 11 is suitably formed using thermal oxidation method. The temperature for this process may be about higher than 900-centigrade degrees. Alternatively, the silicon dioxide layer 11 can also be formed using a chemical vapor deposition (CVD) process at a temperature between about 600 to 800° C. and a pressure between about 0.1 to 10 torr. Further, the silicon dioxide layer 11 also acts as a cushion between the silicon substrate 10 and a subsequent polysilicon layer for reducing stress during subsequent polysilicon layer forming.

Subsequently, an un-doped polysilicon layer as the first conductive layer 12 is formed on the silicon dioxide 11 to a thickness of about 1000 to 2000 angstroms. After the polysilicon layer 12 is formed, a first blanket ion implantation into the polysilicon layer 12, thereby the first blanket ion implantation is doped into the polysilicon layer 12 to form deep implantation region 14 of polysilicon. The first ion type is N-type or P-type conductivity ion. The N-type conductive dopants are such as As (arsenic) or P (phosphorus.) The energy and dosage of the arsenic implantation are about 50 to 70 KeV, 4E16 to 6E16 atoms/cm², respectively. Further, the energy and dosage of the phosphorus implantation are about 40 to 60 KeV, 2E15 to 4E15 atoms/cm².

Turning to FIG. 2, it is the cross sectional view of forming a shallow implantation region of polysilicon according to the present invention. After the deep implantation region 14 of polysilicon is formed, a second blanket ion implantation into the polysilicon layer 12 is performed, thereby the second blanket ion implantation is doped into the polysilicon layer 12 to form shallow implantation region 16 of polysilicon. Thus, the implantation region of the second ion implantation adjacent to the surface of the polysilicon layer 12, wherein the second ion type is N-type or P-type conductivity ion, and the second ion type is the same as the first ion type. The N-type conductive dopants are such as As or P. The energy and dosage of the arsenic implantation are about 10 to 20 KeV, 1E16 to 2E16 atoms/cm², respectively. Further, the energy and dosage of the phosphorus implantation are about 10 to 20 KeV, 1E15 to 2E15 atoms/cm². The thickness of the shallow implantation in the polysilicon layer 12 is less than 100 angstrom.

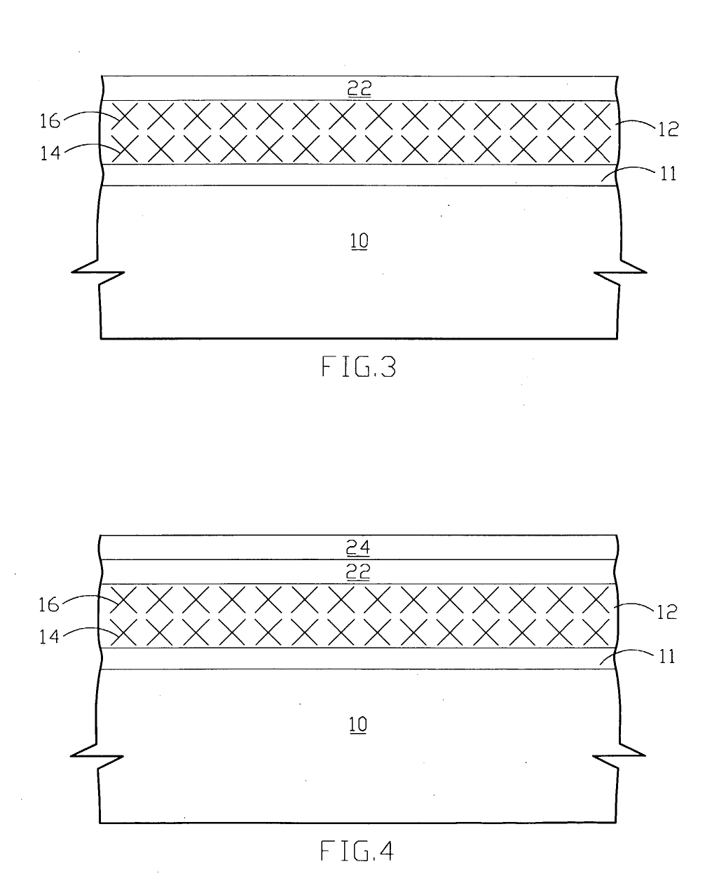

Turning to FIG. 3, it is the cross sectional view of forming a titanium nitride (TiN) layer of the second conductive layer on the polysilicon layer 12 according to the present invention. Any suitable process can deposit the titanium nitride (TiN) layer 22 on the polysilicon layer 12. For example, low pressure chemical vapor deposition (LPCVD), plasma enhanced chemical vapor deposition (PECVD), or high-density plasma chemical vapor deposition (HDPCVD) may be used.

Turning to FIG. 4, it is the cross sectional view of forming a silicide layer 24 of the second conductive layer on the titanium nitride 22 layer according to the present invention. Any suitable process can deposit the silicide layer 24 on the titanium nitride layer 22. For example, low pressure chemical vapor deposition, plasma enhanced chemical vapor deposition, or high-density plasma chemical vapor deposition may be used. The material of the silicide layer 24 can be titanium silicide (TiSi).

Turning to FIG. 5, it is the cross sectional view of forming a silicon nitride layer 26 on the titanium silicide layer 24 according to the present invention. Any suitable process can deposit the silicon nitride layer 26. For example, low pressure chemical vapor deposition, plasma enhanced chemical vapor deposition, or high-density plasma chemical vapor deposition may be used. In the preferred embodiment, the reaction gases used to form silicon nitride layer 26 are SiH₄, NH₃, N₂, N₂O or SiH₂Cl₂, NH₃, N₂, N₂O.

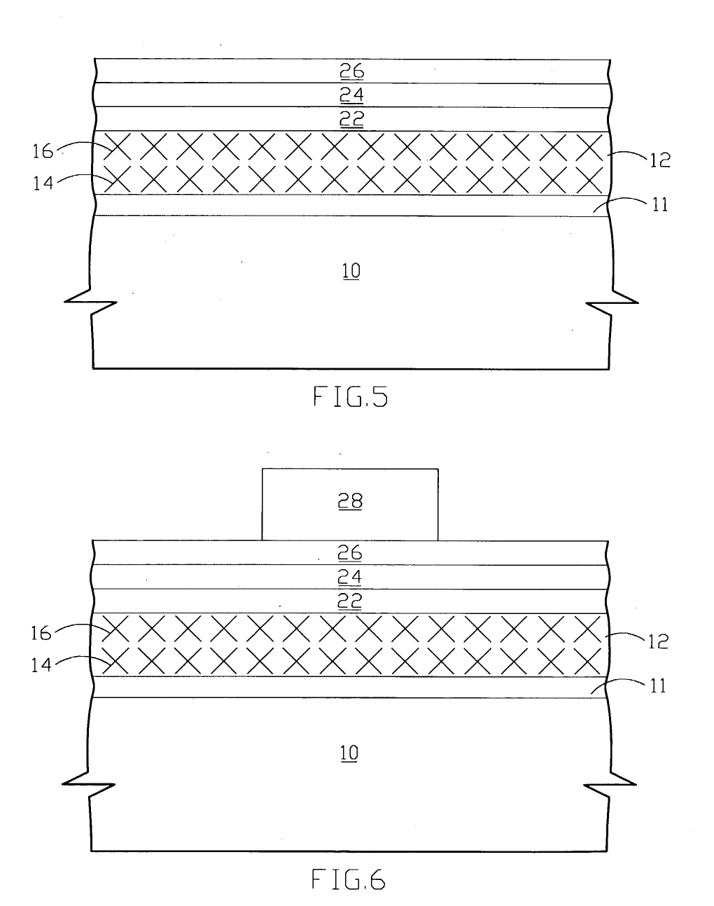

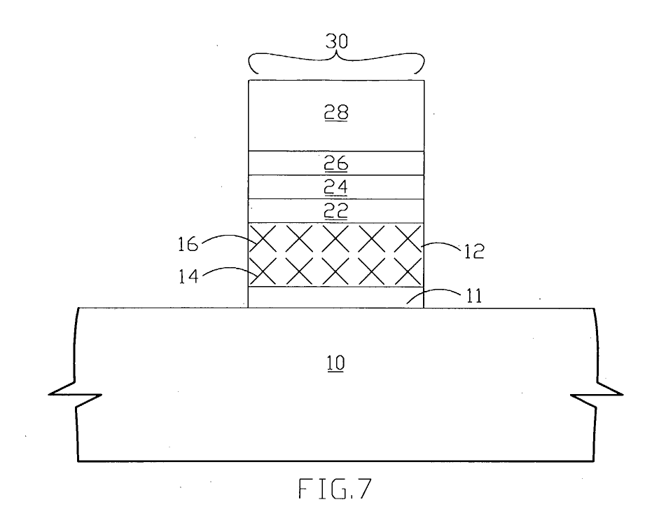

Turning to FIG. 6, it is the cross sectional view of forming a patterned photoresist layer 28 on the silicon nitride layer 26 by using conventional lithography procedure according to the present invention.

FIG. 7 is the cross sectional view of forming a polycide gate according to the present invention. Next, a dry etching process one time by way of using the patterned photoresist layer 28 as an etching mask is performed to etch through in turn the silicon nitride layer 26, the titanium silicide layer 24, the titanium nitride layer 22, the polysilicon layer 12, and the pad oxide layer 11 until forming a gate 30 with double polysilicon implantation, wherein the gate 30 is a polycide gate 30. Finally, the patterned photoresist layer 28 is then removed.

The polycide gate 30 with double implantation region of polysilicon can reduce vertical contact resistance Rc between the titanium silicide layer 24, the titanium nitride layer 22 and the polysilicon layer 12 by means of more ion implantation concentration of surface of polysilicon layer 12.

In a preferred embodiment, the silicon oxide layer 11 may be removed by HF solution or BOE (buffer oxide etching) solution. In the preferred embodiment, the silicon nitride layer 26 is etched using CF₄ plasma as the etchant.

The structure of the polycide gate 30 includes a gate oxide layer 11 formed on a substrate 10. A polysilicon layer 12 as the same gate length with the gate oxide layer 11 is formed on the gate oxide layer 11. A titanium nitride layer 22 as the same gate length with the polysilicon layer 12 is formed on the polysilicon layer 12. A silicide layer 24 as the same gate length with the titanium nitride layer 22 is formed on the titanium nitride layer 22. A silicon nitride layer 26 as the same gate length with the silicide layer 24 is formed on the silicide layer 24.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. A method for forming a polycide gate comprising:
forming a first conductive layer on a gate dielectric layer;
performing a first ion implantation into said first conductive layer;
performing a second ion implantation into said first conductive layer, wherein doped region of said first ion implantation is below doped region of said second ion implantation;
forming a second conductive layer over said first conductive layer;
forming a patterned photoresist layer on said second conductive layer;
performing an etching process one time by way of using said patterned photoresist layer as an etching mask to etch through in turn said second conductive layer, said first conductive layer, and said gate dielectric layer, thereby forming a polycide gate; and
removing said patterned photoresist layer.

2. The method of claim 1, wherein material of said gate dielectric layer is silicon dioxide.

3. The method of claim 1, wherein material of said first conductive layer is polysilicon.

4. The method of claim 1, wherein said second conductive layer comprises a titanium nitride (TiN) layer on said first conductive layer.

5. The method of claim 1, wherein said second conductive layer further comprising a silicide layer on said titanium nitride layer.

6. The method of claim 5, wherein material of said silicide layer is titanium silicon (TiSi).

7. The method of claim 1, further comprising forming a silicon nitride layer on said silicide layer after forming said silicide layer.

8. The method of claim 7, further comprising forming a patterned photoresist layer on said silicon nitride layer after forming said silicon nitride layer.

9. The method of claim 8, further comprising performing an etching process one time by way of using said patterned photoresist layer as an etching mask to etch through in turn said silicon nitride layer, second conductive layer, said first conductive layer, and said gate dielectric layer, thereby forming a polycide gate.

10. The method of claim 9, further comprising removing said patterned photoresist layer after forming said polycide gate.

11. The method of claim 1, wherein said first ion type is P-type conductivity ion.

12. The method of claim 1, wherein said first ion type is N-type conductivity ion.

13. The method of claim 1, wherein said second ion type is P-type conductivity ion.

14. The method of claim 1, wherein said second ion type is N-type conductivity ion.

15. The method of claim 1, wherein the thickness of said second ion implantation in said first conductive layer is less than 100 angstrom (Å).

16. The method of claim 1, further comprising performing said second ion implanting process, a implantation region of said second ion implantation region adjacent to a surface of said first conductive layer.

17. A structure of a polycide gate comprising
a gate dielectric layer on a substrate;
a first conductive layer on said gate dielectric layer, wherein said includes a first ion implantation region and a second ion implantation region, an implantation region of said first ion implantation is below doped region of said ion implantation, and said doped region of said second ion implantation adjacent to a surface of said first conductive layer; and
a second conductive layer on said first conductive layer.

18. The structure of claim 17, wherein material of said gate dielectric layer is silicon dioxide layer.

19. The structure of claim 17, wherein material of said first conductive layer is polysilicon.

20. The structure of claim 17, wherein said first and second ion type are P-type conductivity ion.

21. The structure of claim 17, wherein said first and second ion type are N-type conductivity ion.

22. The structure of claim 17, wherein said second conductive layer comprises a titanium nitride layer on said first conductive layer.

23. The structure of claim 17, wherein said second conductive layer further comprising silicide layer on said titanium nitride layer.

24. The structure of claim 23, wherein material of said silicide layer is titanium silicon (TiSi).

25. The structure of claim 17, further comprising a silicon on said second conductive layer.

26. The structure of claim 17, wherein material of said silicide layer is titanium silicide (TiSi).

27. The structure of claim 17, wherein the thickness of said second ion implantation in said first conductive layer is less than 100 angstrom (Å).
